(19) United States
(12) Patent Application Publication
(10) Pub. No.: US 2016/0162086 A1
(43) Pub. Date: Jun. 9, 2016

(54) TOUCH CONTROL ELECTRODE, TOUCH SCREEN, AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Jiuxia Yang, Beijing (CN); Feng Bai, Beijing (CN); Jiantao Liu, Beijing (CN)

(21) Appl. No.: 14/799,449

(22) Filed: Jul. 14, 2015

(30) Foreign Application Priority Data
Dec. 3, 2014 (CN) 201410725283.6

(51) Int. Cl. G06F 3/041; C23C 14/24; G06F 3/045

(52) U.S. Cl. CPC G06F 3/0412; G06F 3/045; C23C 14/24; G06F 2203/04103

(57) ABSTRACT

A touch control electrode, the square resistance of the touch control electrode can be reduced, thereby improving sensitivity of the touch screen. The material of the touch control electrode comprises doped graphene.

### RELATED APPLICATIONS

The present application claims the benefit of Chinese Patent Application No. 201410725283.6, filed on Dec. 3, 2014, the entire disclosure of which is incorporated herein by reference.

### TECHNICAL FIELD

This disclosure relates to the field of display technology, particularly relates to a touch control electrode and fabricating method thereof, a touch screen, and a display device.

### BACKGROUND ART

Generally, the display device comprises a touch screen so as to realize operation of the display device only by touching the display screen of the display device without mounting the mechanical button panel. Wherein the touch screen comprises a touch control electrode, the common materials of the touch control electrode are tin indium oxide and metal mesh.

The inventor finds that the square resistance of the touch control electrode is relatively high when the above materials are used to fabricate the touch control electrode, such that the fabricated touch screen has a relatively low sensitivity, consequently, the user needs to touch the display screen for many times to operate the display device, thereby the life time of the touch screen will be reduced, and the user experience will be relatively bad.

### SUMMARY OF THE DISCLOSURE

The technical problem to be solved by this disclosure lies in providing a touch control electrode and fabricating method thereof, a touch screen, and a display device, which can reduce the square resistance of the touch control electrode, thereby improving sensitivity of the touch screen.

In order to solve the above technical problem, this disclosure provides a touch control electrode using the following technical solutions:

A touch control electrode, the material of the touch control electrode comprises doped graphene.

The doping material of the doped graphene comprises aluminum chloride and/or zinc iodide.

The touch control electrode comprises at least one layer of doped graphene.

The touch control electrode further comprises at least one layer of graphene located on one side of the doped graphene, and one layer of graphene located on the other side of the doped graphene.

The embodiment of this disclosure provides a touch control electrode, the material of the touch control electrode comprising doped graphene, because the doping material in the doped graphene can increase consistency of charges in the touch control electrode, the conductivity of the touch control electrode can be increased, thereby reducing the square resistance of the touch control electrode and improving sensitivity of the touch screen, so as to increase the lift time of the touch screen and improve user experience.

In an embodiment of the touch control electrode, the touch control electrode further comprises at least one layer of graphene located on one side of the doped graphene, and one layer of graphene located on the other side of the doped graphene.

Optionally, the doped graphene is made by doping the graphene through vacuum evaporation.

Optionally, an evaporation chamber of the vacuum evaporation has a vacuum degree of above 10⁻⁴ torr at room temperature, an evaporation temperature of the vacuum evaporation is 150° C.˜500° C.

The embodiment of this disclosure further provides a touch screen comprising a touch control electrode as stated in any of the above.

The touch screen is flexible.

The embodiment of this disclosure further provides a display device comprising a touch screen as stated above.

The touch screen is successively arranged on at least two adjacent surfaces of the display device.

Another technical problem to be solved by this disclosure lies in providing a method of fabricating a touch control electrode, the method comprising:
forming a pattern comprising the touch control electrode on a substrate, the material of the touch control electrode comprising doped graphene.

The step of forming a pattern comprising the touch control electrode on a substrate comprises the steps of:
forming a layer of graphene on the substrate;
doping the graphene to form a layer of doped graphene;
repeating the above steps for N−1 times, so as to form N layers of doped graphene on the substrate, wherein N is an integer greater than or equal to 1;
forming a pattern comprising the touch control electrode via patterning process.

The step of forming a pattern comprising the touch control electrode on a substrate comprises the steps of:
forming a layer of graphene with a pattern comprising the touch control electrode on the substrate;
doping the graphene to form a layer of graphene;
repeating the above steps for N−1 times, so as to form N layers of doped graphene on the substrate, wherein N is an integer greater than or equal to 1.

The step of forming a pattern comprising the touch control electrode on a substrate comprises the steps of:
forming at least two layers of graphene with a pattern comprising the touch control electrode on the substrate;
doping the layer of graphene that is farthest from the substrate, to form a layer of doped graphene;
forming a layer of graphene with a pattern comprising the touch control electrode on the substrate on which the doped graphene is formed.
the step of doping the graphene comprises: doping the graphene through the method of vacuum evaporation.

The evaporation chamber of the vacuum evaporation has a vacuum degree of above 10⁻⁴ torr at room temperature, the evaporation temperature of the vacuum evaporation is 150° C.˜500° C.

The embodiment of this disclosure provides a method of fabricating a touch control electrode, the method comprising: forming a pattern comprising the touch control electrode on a substrate, the material of the touch control electrode comprising doped graphene. Because the doping material in the doped graphene can increase consistency of charges in the touch control electrode, the conductivity of the touch control electrode can be increased, thereby reducing the square resistance of the touch control electrode and improving sensitivity of the touch screen, so as to increase the life time of the touch screen and improve user experience.

### BRIEF DESCRIPTION OF DRAWINGS

In order to explain the technical solutions in the embodiments of this disclosure or the prior art more clearly, next the drawings to be used in description of the drawings will be introduced briefly. Apparently, the drawings described below are only some embodiments of this disclosure. The ordinary skilled person in the art can also obtain other drawings based on these drawings without paying any creative work.

FIG. 1 is a sectional schematic view of a first touch control electrode in an embodiment of this disclosure;

FIG. 2 is a sectional schematic view of a second touch control electrode in an embodiment of this disclosure;

FIG. 3 is a flow chart of a first fabricating method of a touch control electrode in an embodiment of this disclosure;

FIG. 4 is a flow chart of a second fabricating method of a touch control electrode in an embodiment of this disclosure;

FIG. 5 is a flow chart of a third fabricating method of a touch control electrode in an embodiment of this disclosure.

### EXPLANATIONS OF REFERENCE SIGNS

1—doped graphene; 2—substrate; 3—graphene

### SPECIFIC IMPLEMENTING MODES

Next, the technical solutions in the embodiments of this disclosure will be described clearly and completely in combination with the drawings in the embodiments of this disclosure. Apparently, the embodiments described are only part rather than all of the embodiments of this disclosure. All the other embodiments obtained by the ordinary skilled person in the art based on the embodiments in this disclosure without paying any creative work belong to the protection scope of this disclosure.

### Embodiment I

The embodiment of this disclosure provides a touch control electrode, the material of the touch control electrode comprising doped graphene. Wherein the doping material in the doped graphene can increase consistency of charges in the touch control electrode, such that the conductivity of the touch control electrode is increased, and because the conductivity is in inverse proportion to the square resistance, the square resistance of the touch control electrode can be reduced and the sensitivity of the touch screen can be improved. For example, when the light transmittance of the touch control electrode is same, the square resistance of the touch control electrode, the material of which comprises graphene, is 120 Ω, while the square resistance of the touch control electrode, the material of which comprises doped graphene, is below 10 Ω.

Specifically, the doping materials of the doped graphene may be one or two of aluminum chloride and zinc iodide, and may also be other materials that can increase consistency of the charges in the touch control electrode but would not reduce the light transmittance of the touch control electrode.

In order to facilitate understanding of the skilled person in the art, the embodiment of this disclosure provides two specific structures of the touch control electrode.

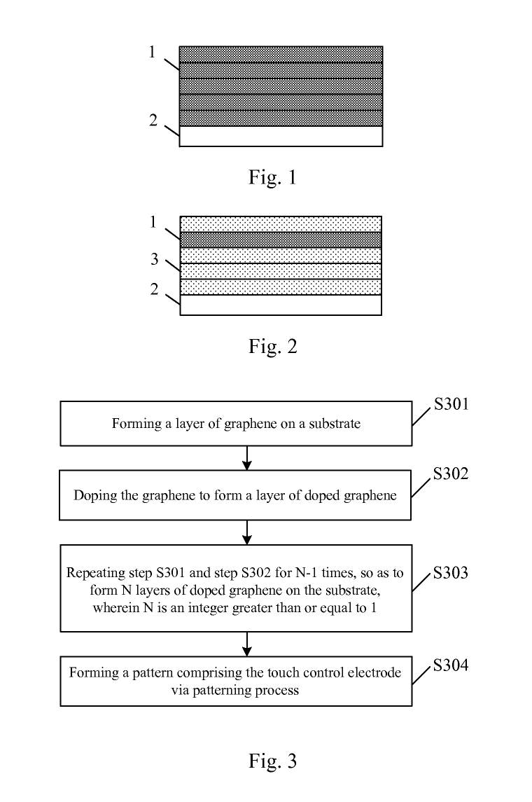

The touch control electrode of the first structure comprises at least one layer of doped graphene. For example, as shown in FIG. 1, the touch control electrode comprises five layers of doped graphene 1, and other components such as a substrate 2. When the number of layers of the doped graphene 1 in the touch control electrode increases, the consistency of the charged in the touch control electrode will be increased, hence, the square resistance of the touch control electrode will be reduced. Therefore, a touch control electrode with a different square resistance can be obtained by changing the number of layers of the doped graphene 1 in the touch control electrode.

The touch control electrode with the above structure can be applied in a display device in the On-cell, In-cell, Out-cell and OGS modes, wherein, in the On-cell mode, the touch control electrode is embedded between the color filter and the polarizer of the display device; in the In-cell mode, the touch control electrode is embedded between the liquid crystal molecule layer and the array substrate; in the Out-cell mode, the touch control electrode is arranged at the outside of the display device; in the OGS mode, the touch control electrode is formed on the protective glass directly. In the On-cell, In-cell, Out-cell and OGS modes, the requirements on the square resistance of the touch control electrode are different, therefore, different number of layers of doped graphene 1 can be arranged in the touch control electrode with the first to accommodate the different requirements on the square resistance of the touch control electrode in the above four modes.

The touch control electrode of the second structure, besides at least one layer of doped graphene 1, further comprises at least one layer of graphene 3 located on one side of the doped graphene 1 and one layer of graphene 3 located on the other side of the doped graphene 1. For example, as shown in FIG. 2, the touch control electrode comprises three layers of graphene 3, one layer of doped graphene 1 and one layer of graphene 3 located on the substrate 2 successively. Wherein, the one layer of doped graphene 1 located on the graphene 3 can increase consistency of the charges in the touch control electrode, thus the square resistance of the touch control electrode can be reduced. However, since the distribution of the doping material in this layer of doped graphene 1 might be uneven, the charge consistency at a certain position of the touch control electrode would be greater than the charge consistency at another position, hence, in order to reduce the influence of different charge consistencies at different positions in the touch control electrode to the square resistance, one layer of graphene 3 can be increased on the doped graphene 1, so as to reduce the difference between the charge consistencies at different positions, thereby not generating influence on the square resistance while reducing the square resistance of the touch control electrode.

In the second structure, since the touch control electrode comprises multiple layers of graphene, when the number of layers of the materials comprised by the touch control electrode is same, the square resistance of the touch control electrode with the second structure is greater than the square resistance of the touch control electrode with the first structure, here, the touch control electrode with the second structure may be applicable in modes such as On-cell in which the requirement on the square resistance of the touch control electrode is not high.

In the above two structures, when the layer numbers of the materials comprised by the touch control electrode are same, since the touch control electrode with the first structure only comprises at least one layer of doped graphene 1, the square resistance of the touch control electrode with the first structure is less than the square resistance of the touch control electrode with the second structure, such that the sensitivity of the touch screen using the touch control electrode with the first structure is higher; moreover, when the layer number of the material comprised by the touch control electrode is limited, the changing range of the square resistance of the touch control electrode with the first structure is relatively large, the application scope is relatively wide, hence, the touch control electrode with the first structure is preferred in the embodiment of this disclosure, i.e., the touch control electrode consists of at least one layer of doped graphene 1.

The embodiment of this disclosure provides a touch control electrode, the material of the touch control electrode comprising doped graphene, because the doping material in the doped graphene can increase consistency of charges in the touch control electrode, the conductivity of the touch control electrode can be increased, thereby reducing the square resistance of the touch control electrode and improving sensitivity of the touch screen, so as to increase the lift time of the touch screen and improve user experience.

In addition, the embodiment of this disclosure further provides a touch screen, the touch screen comprising a touch control electrode in the above implementing mode. Specifically, the touch screen may comprise one or two layers of touch control electrodes, when the touch screen comprises two layers of touch control electrodes, there is an insulating layer between the two layers of touch control electrodes. Wherein, the material of the touch control electrode comprises doped graphene 1, since the graphene 3 has flexibility, the doped graphene 1 also has flexibility, hence, when other components such as substrate 2 comprised by the touch screen has flexibility, the touch screen has flexibility and is flexible, here the touch screen can be used in a flexible display device such as electronic paper, a wearable display device, and may also be used in other flexible devices.

In addition, the embodiment of this disclosure further provides a display device, the display device comprising a touch screen in the above implementing mode. The display device may be any flexible and inflexible product or component with the display function, such as a liquid crystal panel, a tablet computer, a television, a display, a laptop, and the like.

Specifically, since the touch screen is flexible, the touch screen can be successively arranged on at least two adjacent surfaces of the display device. When the control software of the touch screen arranged at the front side of the display device differs from the control software of the touch screen arranged at the side or back side of the display device, the display device can be operated without lighting up the display screen located at the front side of the display device, thus energy consumption can be saved, the duration of the display device can be prolonged. Moreover, the number of touch keys arranged at the front side of the display device can be reduced by arranging the touch screen at the side or back side of the display device, thereby increasing the effective display area of the display screen.

### Embodiment II

The embodiment of this disclosure provides a fabricating method for fabricating a touch control electrode as stated in Embodiment I, the fabricating method comprising: forming a pattern comprising the touch control electrode on the substrate, the material of the touch control electrode comprising doped graphene.

Specifically, the embodiment of this disclosure provides three specific fabricating methods of forming a pattern comprising the touch control electrode on the substrate:

The first fabricating method, as shown in FIG. 3, comprises the steps of:
S301. Forming a layer of graphene on the substrate.

Specifically, a layer of graphene film can be attached on the substrate directly, or a layer of graphene can be formed on the substrate through the method of chemical vapor deposition.
S302. Doping the above graphene to form a layer of doped graphene.
S303. Repeating step S301 and step S302 for N−1 times, so as to form N layers of doped graphene on the substrate, wherein N is an integer greater than or equal to 1.

Specifically, the value of N can be determined based on the requirement on the square resistance of the touch control electrode in the On-cell, In-cell, Out-cell and OGS modes.
S304. Forming a pattern comprising the touch control electrode via patterning process.

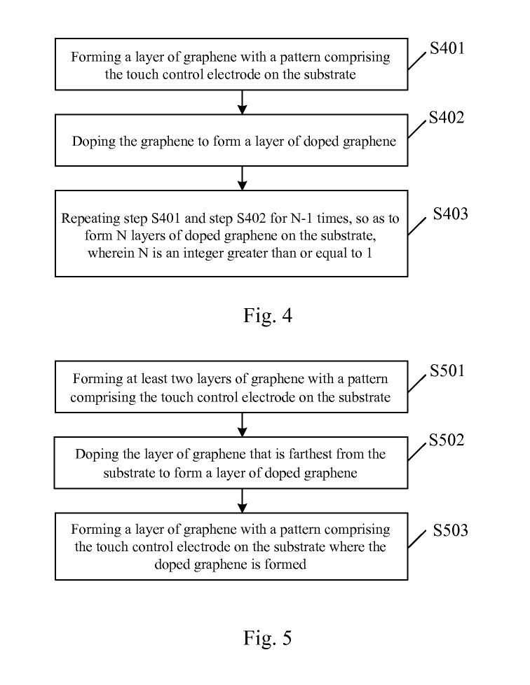

The second fabricating method, as shown in FIG. 4, comprises the steps of:
S401. Forming a layer of graphene with a pattern comprising the touch control electrode on the substrate.

Specifically, a layer of graphene film with a pattern comprising the touch control electrode can be attached on the substrate directly; or a layer of graphene can be formed on the substrate through the method of chemical vapor deposition, and then the pattern comprising the touch control electrode is formed via patterning process, and a layer of graphene with a pattern comprising the touch control electrode can also be formed on the substrate through other methods, which will not be defined specifically in this disclosure.
S402. Doping the graphene to form a layer of doped graphene.
S403. Repeating step S401 and step S402 for N−1 times, so as to form N layers of doped graphene, wherein N is an integer greater than or equal to 1.

Specifically, the value of N can be determined based on the requirement on the square resistance of the touch control electrode in the On-cell, In-cell, Out-cell and OGS modes.

The third fabricating method, as shown in FIG. 5, comprises the steps of:
S501. Forming at least two layers of graphene with a pattern comprising the touch control electrode on the substrate.

Specifically, at least two layers of graphene film with a pattern comprising the touch control electrode can be attached on the substrate directly, or at least two layers of graphene can be formed on the substrate, and then the pattern comprising the touch control electrode is formed via patterning process, which will not be defined specifically in this disclosure.
S502. Doping the layer of graphene that is farthest from the substrate to form a layer of doped graphene.
S503. Forming a layer of graphene with a pattern comprising the touch control electrode on the substrate where the doped graphene is formed.

Specifically, a layer of graphene film with a pattern comprising the touch control electrode can be attached directly on the substrate where the doped graphene is formed, or a layer of graphene film with a pattern comprising the touch control electrode can be formed on the substrate where the doped graphene is formed through other methods.

In the above three fabricating methods, the doping method for doping the graphene is vacuum evaporation method, wherein the evaporation chamber of the vacuum evaporation has a vacuum degree of above 10⁻⁴ torr at room temperature, the evaporation temperature of the vacuum evaporation is 150° C.˜500° C.

Moreover, in the above three fabricating methods, because the first fabricating method does not need to perform patterning for many times compared with the second fabricating method, the process complexity is relatively low, which can increase the production yield. Furthermore, because the square resistance of the touch control electrode fabricated by the first fabricating method is relatively low compared with the third fabricating method, the embodiment of this disclosure preferably chooses the first method as the method for fabricating the touch control electrode.

In addition, when the touch screen comprises two layers of touch control electrodes, it is further required to form an insulating layer on a layer of touch control electrode after the layer of touch control electrode is fabricated using any one of the above three fabricating methods, and, form another layer of touch control electrode on the insulating layer using any one of the above three fabricating methods.

The embodiment of this disclosure provides a method of fabricating a touch control electrode, the method comprising: forming a pattern comprising the touch control electrode on a substrate, the material of the touch control electrode comprising doped graphene. Because the doping material in the doped graphene can increase consistency of charges in the touch control electrode, the conductivity of the touch control electrode can be increased, thereby reducing the square resistance of the touch control electrode and improving sensitivity of the touch screen, so as to increase the lift time of the touch screen and improve user experience.

What are stated above are only specific implementing modes of the present invention, however, the protection scope of the present invention is not limited to this, any modifications or replacements that the skilled person familiar with the present technical field can easily think of within the technical scope disclosed by the present invention should be covered within the protection scope of the present invention. Therefore, the protection scope of the present invention should be based on the protection scopes of the claims.

1. A touch control electrode, wherein a material of the touch control electrode comprises doped graphene.

2. The touch control electrode according to claim 1, wherein a doping material of the doped graphene comprises aluminum chloride and/or zinc iodide.

3. The touch control electrode according to claim 1, wherein the touch control electrode comprises at least one layer of the doped graphene.

4. The touch control electrode according to claim 2, wherein the touch control electrode comprises at least one layer of the doped graphene.

5. The touch control electrode according to claim 3, wherein the touch control electrode further comprises at least one layer of graphene located on one side of the doped graphene, and one layer of graphene located on the other side of the doped graphene.

6. A touch screen, comprising a touch control electrode, wherein a material of the touch control electrode comprises doped graphene.

7. The touch screen according to claim 6, wherein the touch screen is flexible.

8. A method of fabricating a touch control electrode, comprising:
forming a pattern comprising the touch control electrode on a substrate, a material of the touch control electrode comprising doped graphene.

9. The method of fabricating a touch control electrode according to claim 8, wherein forming a pattern comprising the touch control electrode on a substrate comprises the steps of:
forming a layer of graphene on the substrate;
doping the graphene to form a layer of doped graphene;
repeating the above steps for N−1 times, so as to form N layers of doped graphene on the substrate, wherein N is an integer greater than or equal to 1;
forming a pattern comprising the touch control electrode via patterning process.

10. The method of fabricating a touch control electrode according to claim 8, wherein forming a pattern comprising the touch control electrode on a substrate comprises the steps of:
forming a layer of graphene with a pattern comprising the touch control electrode on the substrate;
doping the graphene to form a layer of doped graphene;
repeating the above steps for N−1 times, so as to form N layers of doped graphene on the substrate, wherein N is an integer greater than or equal to 1.

11. The method of fabricating a touch control electrode according to claim 8, wherein forming a pattern comprising the touch control electrode on a substrate comprises the steps of:
forming at least two layers of graphene with a pattern comprising the touch control electrode on the substrate;
doping the layer of graphene that is farthest from the substrate, to form a layer of doped graphene;
forming a layer of graphene with a pattern comprising the touch control electrode on the substrate on which the doped graphene is formed.

12. The method of fabricating a touch control electrode according to any one of claim 8, wherein doping the graphene comprises: doping the graphene through the method of vacuum evaporation.

13. The method of fabricating a touch control electrode according to claim 12, wherein the evaporation chamber of the vacuum evaporation has a vacuum degree of above 10⁻⁴ torr at room temperature, the evaporation temperature of the vacuum evaporation is 150° C.˜500° C.
